(19) United States
(12) Patent Application Publication
(10) Pub. No.: US 2025/0393296 A1
(43) Pub. Date: Dec. 25, 2025

(54) SEMICONDUCTOR STRUCTURE

(71) Applicant: MEDIATEK INC., Hsinchu City (TW)

(72) Inventors: Shih-Chuan CHIU, Hsinchu City (TW); Chia-Hsin HU, Hsinchu City (TW); Zheng ZENG, Hsinchu City (TW)

(21) Appl. No.: 19/098,035

(22) Filed: Apr. 2, 2025

Related U.S. Application Data
(60) Provisional application No. 63/661,916, filed on Jun. 20, 2024.

(51) Int. Cl. H10D 84/40

(52) U.S. Cl. CPC H10D 84/40

(57) ABSTRACT

A semiconductor structure is provided. The semiconductor structure includes a trench isolation feature, a gate structure, and a source/drain contact. The gate structure and the source/drain contact next to the gate structure are disposed directly on the trench isolation feature. The gate structure and the source/drain contact form electrodes of a capacitor.

### CROSS REFERENCE TO RELATED APPLICATIONS

This application claims the benefit of U.S. Provisional Application No. 63/661,916, filed Jun. 20, 2024, the entirety of which is incorporated by reference herein.

### BACKGROUND OF THE DISCLOSURE

### Field of the Disclosure

The present disclosure relates to a semiconductor structure and, in particular, to a capacitor fabricated in a semiconductor structure.

### Description of the Related Art

In recent years, advanced integrated circuit (IC) devices have become increasingly multifunctional and have been scaled down in terms of size. Although the scaling-down process generally increases production efficiency and lowers the associated costs, it has also increased the complexity of processing and manufacturing IC devices. For example, Fin Field-Effect Transistor devices (FinFETs) have been introduced to replace planar transistor devices. Among these FinFETs, gate-all-around (GAA) structures such as nanosheet metal-oxide-semiconductor field-effect transistor devices (MOSFET) with excellent electrical characteristics have been developed. These characteristics include improved power performance and better area-scaling than what is available using current FinFET technologies.

Although existing semiconductor structures including nanosheet transistor devices and methods for manufacturing the same have been adequate for their intended purposes, they have not been entirely satisfactory in all respects. For example, it is a challenge to fabricate low leakage capacitors using the gate-all-around (GAA) processes.

Thus, a novel semiconductor structure is needed to reduce the amount of leakage of the device.

### BRIEF SUMMARY OF THE DISCLOSURE

An embodiment of the present disclosure provides a semiconductor structure. The semiconductor structure includes a trench isolation feature, a gate structure, and a source/drain contact. The gate structure and the source/drain contact next to the gate structure are disposed directly on the trench isolation feature. The gate structure and the source/drain contact form electrodes of a capacitor.

An embodiment of the present disclosure provides a semiconductor structure. The semiconductor structure includes a semiconductor substrate, a trench isolation feature, a first gate structure, and first contacts. The semiconductor substrate has an active region and an isolation region surrounding the active region. The trench isolation feature is disposed in the isolation region. The first gate structure is disposed on and in contact with the trench isolation feature. The first contacts are disposed on opposite sides of the first gate structure and in contact with trench isolation feature. The first gate structure is electrically coupled to a first power terminal, and the first contacts are electrically coupled to a second power terminal.

### BRIEF DESCRIPTION OF THE DRAWINGS

The present disclosure can be more fully understood by reading the subsequent detailed description and examples with references made to the accompanying drawings, wherein:

FIG. 1 is a top view of a semiconductor structure in accordance with some embodiments of the disclosure; and

FIG. 2 is a cross-sectional view of the semiconductor structure along the line A-A′ of FIG. 1 in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

Advanced integrated circuit (IC) devices have become increasingly multifunctional and have been scaled down in size. Although the scaling down process generally increases production efficiency and lowers the associated costs, it has also increased the complexity of processing and manufacturing IC devices. For example, Fin Field-Effect Transistors (FinFETs) have been introduced to replace planar transistors. Among these FinFETs, gate-all-around (GAA) structures such as nanosheet or nanowire metal-oxide-semiconductor field-effect transistors (MOSFET) have been developed to possess excellent electrical characteristics, such as better power performance and area scaling compared to the current FinFET technologies The conventional capacitors mainly include lateral capacitors and vertical capacitors. The lateral capacitors are composed of the metal gate, the metal source/drain contact, and the dielectric layer located between the metal gate and the metal source/drain contacts. The vertical capacitors are composed of the high-k dielectric/metal gate (HKMG) structure, the silicon nanosheet channel layer, and the interfacial silicon oxide layer formed between the silicon nanosheet channel layers and the HKMG structure. Since the interfacial silicon oxide layer has a thin thickness (of about 1 nm), it is a challenge to improve the leakage of the vertical capacitors.

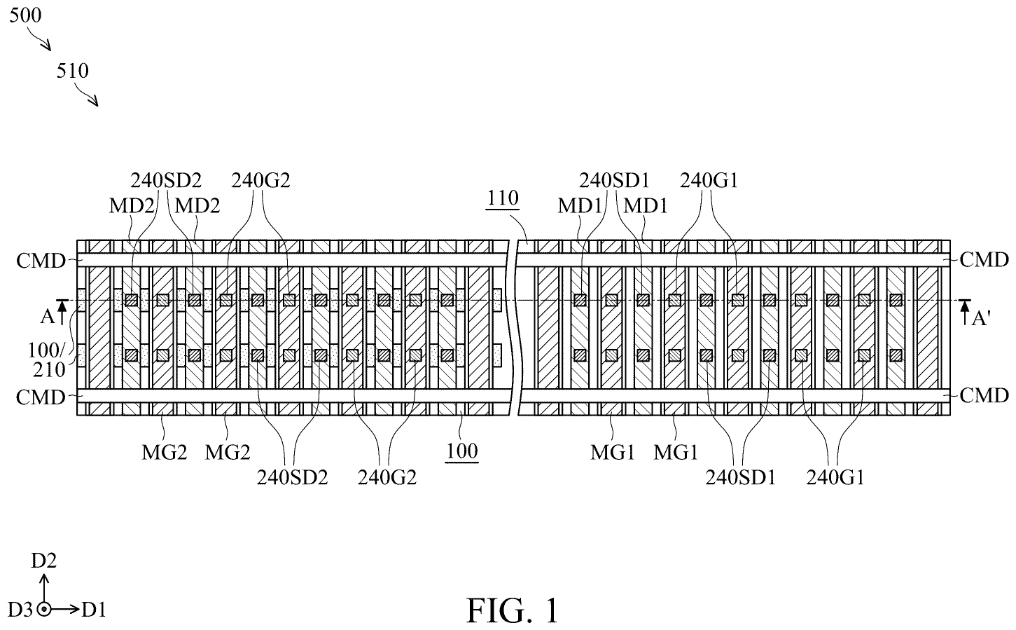

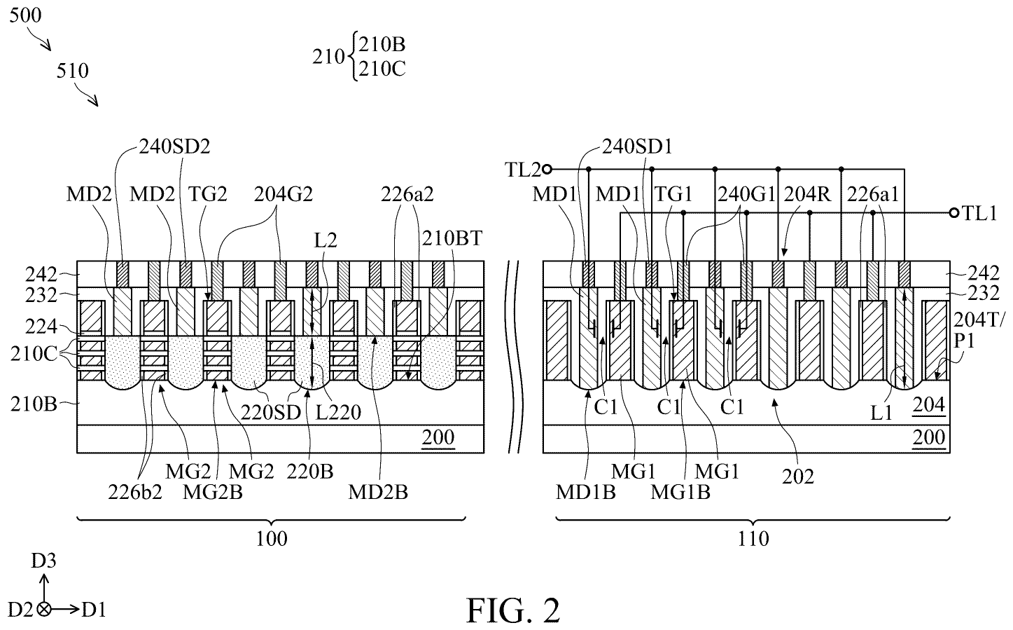

FIG. 1 is a top view of a semiconductor structure 500 in accordance with some embodiments of the disclosure. FIG. 2 is a cross-sectional view of the semiconductor structure 500 along the line A-A′ of FIG. 1 in accordance with some embodiments of the disclosure. FIG. 1 also illustrates as a layout of the semiconductor structure 500 in accordance with some embodiments of the disclosure. In some embodiments, the semiconductor structure 500 is fabricated by the GAA processes. For illustration, a dielectric layer (an interlayer dielectric (ILD) layer) 232 and an intermetal dielectric (IMD) layer 242 (shown in FIG. 2) formed over GAA field-effect transistor devices 510 are hidden in FIG. 1.

As shown in FIG. 1 and FIG. 2, the semiconductor structure 500 includes a semiconductor substrate 200, a trench isolation feature 204, at least one first gate structure MG1 and at least one first contact MD1. In some embodiments, the material of the semiconductor substrate 200 includes Si, SiP, SiGe, SiC, SiPC, Ge, SOI-Si, SOI—SiGe, III-VI material, or a combination thereof. In some embodiments, the semiconductor substrate 200 is electrically floating.

In some embodiments, the semiconductor substrate 200 includes one or more active regions 100 and one or more isolation regions 110 surrounding the active regions 100. The isolation regions 110 are located where trenches 202 formed in the semiconductor substrate 200. In addition, the active regions 100 along direction D1 (also called a channel length direction) are defined by the trenches 202. In some embodiments, the active regions 100 are provided for GAA field-effect transistor devices 510 formed on it.

The trench isolation feature 204 is disposed on the semiconductor substrate 200 and in the isolation region 110. In addition, the trench isolation feature 204 may partially fill the trenches 202. As shown in FIG. 2, the trench isolation feature 204 may include one or more elongated recess portions 204R arranged periodically along direction D1. The elongated recess portions 204R are recessed from a top surface 204T of the trench isolation feature 204. In some embodiments, the elongated recess portions 204R may extend along direction D2 (also called a channel width direction) that is different from direction D1.

In some embodiments, the trench isolation feature 204 forms shallow trench isolation (STI) structures. In some embodiments, the trench isolation feature 204 includes silicon oxide, silicon nitride, silicon oxynitride (SiON), another suitable insulating material, or a combination thereof. In some embodiments, the trench isolation feature 204 is formed by performing a depositing process of an insulating material (not shown), a planarization process and a recessing process. The depositing process may be performed to form the insulating material (not shown) filling the trenches 202. The depositing process may include thermal growth, spin-on coating, chemical vapor deposition (CVD), high density plasma CVD (HDP-CVD), physical vapor deposition (PVD), atomic layer deposition (ALD), or any other applicable deposition processes. The planarization process may be performed so that a top surface of the insulating material (not shown) is level with a top surface of each of the fin structures 210. The planarization process may include chemical mechanical polishing (CMP) or any other applicable planarization processes. In addition, the recessing process may be performed to recess the insulating material to form the isolation features 204. The recessing process may include reactive ion etching (RIE), dry etching, wet etching, or any other applicable etching processes.

At least one gate structure MG1 is disposed directly on the trench isolation feature 204. In addition, a bottom MG1B of the first gate structure MG1 may be in contact with the trench isolation feature 204.

In some embodiments, the first gate structures MG1 are strip shaped. They are arranged along direction D1 (which is substantially along the lengthwise direction of the channel layers of the GAA field-effect transistor devices 510) and extend along direction D2 (which is substantially perpendicular to the lengthwise direction of the channel layers of the GAA field-effect transistor devices 510). In some embodiments, the first gate structures MG1 are arranged periodically along direction D1.

In some embodiments, the first gate structure MG1 is disposed on a portion P1 of the top surface 204T of the trench isolation feature 204 between the elongated recess portions 204R. More specifically, the portion P1 of the top surface 204T of the trench isolation feature 204 may extend along direction D2. The strip-shaped first gate structures MG1 are respectively disposed in the corresponding portions P1 of the top surface 204T of the trench isolation feature 204. In addition, the extending direction (i.e., the lengthwise direction) of the strip-shaped first gate structure MG1 and the extending direction (i.e., the lengthwise direction) of the portions P1 of the top surface 204T of the trench isolation feature 204 are parallel to each other. In some embodiments, each of the portions P1 of the top surface 204T of the trench isolation feature 204 is in contact with one of the first gate structure MG1. In the top view as shown in FIG. 1, the portions P1 of the top surface 204T of the trench isolation feature 204 are located directly below the corresponding strip-shaped first gate structure MG1.

In some embodiments, the first gate structure MG1 includes a gate dielectric layer and a gate electrode layer (not shown) formed on the gate dielectric layer. In some embodiments, the gate dielectric layer includes high-k dielectric material, other applicable dielectric material or combinations thereof. In some embodiments, the gate dielectric layer is formed by chemical vapor deposition (CVD), physical vapor deposition, (PVD), atomic layer deposition (ALD) or other applicable deposition processes. In some embodiments, the gate electrode layer includes conductive materials, such as metals. In some embodiments, the gate electrode layer is formed by chemical vapor deposition (CVD), physical vapor deposition, (PVD), atomic layer deposition (ALD) or other applicable deposition processes.

The semiconductor structure 500 may further include gate spacers 226a1. The gate spacers 226a1 may be disposed on opposite sidewalls of each of the first gate structures MG1. In some embodiments, the gate spacer 226a1 includes dielectric materials such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the gate spacer 226a1 may be formed by a deposition process and a subsequent etching back process. The deposition process may include chemical vapor deposition (CVD), flowable chemical vapor deposition, subatmospheric chemical vapor deposition (SACVD), physical vapor deposition (PVD), atomic layer deposition (ALD), or any other applicable deposition processes. The etching back process may include wet etching, dry etching or a combination thereof.

The semiconductor structure 500 may further include a dielectric layer 232 (also called an interlayer dielectric (ILD) layer 232). The dielectric layer 232 is formed covering the first gate structures MG1. More specifically, the dielectric layer 232 may cover the top surface and opposite sidewalls of the first gate structure MG1 and filling spaces (not shown) between the first gate structure MG1. In some embodiments, the dielectric layer 232 includes borophosphosilicate glass (BPSG), fused silica glass (FSG), phosphosilicate glass (PSG), boron doped silicon glass (BSG), tetraethylorthosilicate (TEOS) oxide, and/or other applicable dielectric materials In some embodiments, the dielectric layer 232 is formed by chemical vapor deposition (CVD), physical vapor deposition, (PVD), atomic layer deposition (ALD) or other applicable deposition processes.

At least one first contact MD1 is disposed directly on the trench isolation feature 204 and passes through the dielectric layer 232. In addition, a bottom MD1B of the first contact MD1 may be in contact with the trench isolation feature 204. In some embodiments, the top (not shown) of first contact MD1 is aligned with the top surface (not shown) of the dielectric layer 232.

In some embodiments, the first contacts MD1 are strip shaped. They are arranged along direction D1 and extend along direction D2. The first gate structures MG1 and the first contacts MD1 may be parallel to each other in directions D2 and D3.

In some embodiments, the first contacts MD1 are arranged periodically along direction D1. The first contacts MD1 may be arranged alternatingly with the first gate structures MG1. For example, each of the first gate structures MG1 is located between two of the first contacts MD1. Each of the first contacts MD1 is located between two of the first gate structures MG1. For example, the adjacent two first contacts MD1 may be disposed on opposite sides of the corresponding first gate structure MG1.

In some embodiments, the strip-shaped first contacts MD1 are respectively disposed in the elongated recess portions 204R. In addition, the extending direction (i.e., the lengthwise direction) of the strip-shaped first contacts MD1 and the extending direction (i.e., the lengthwise direction) of the elongated recess portions 204R are parallel to each other. In some embodiments, each of the elongated recess portions 204R is in contact with one of the first contacts MD1. In the top view as shown in FIG. 1, the elongated recess portions 204R are located directly below the corresponding strip-shaped first contacts MD1.

In some embodiments, the gate electrode layer of the first gate structure MG1 and the first contact MD1 are formed of metals.

The semiconductor structure 500 may further include vias 240G1, 240SD1 and the intermetal dielectric (IMD) layer 242 formed on the dielectric layer 232, the first gate structures MG1 and the first contacts MD1. The vias 240G1 are formed passing through the intermetal dielectric (IMD) layer 242 and a portion of the dielectric layer 232 directly above the first gate structures MG1. In addition, the vias 240G1 are electrically coupled to the first gate structures MG1. The vias 240SD1 are located directly above the first contacts MD1. The vias 240SD1 are formed passing through the intermetal dielectric (IMD) layer 242. In addition, the vias 240SD1 are electrically coupled to the first contacts MD1.

In the isolation region 110, the first gate structures MG1 are all electrically coupled to a first terminal TL1 by the vias 240G1. The first contacts MD1 are all electrically coupled to a second terminal TL2 by the vias 240SD1. For example, the first terminal TL1 is a power supply terminal (VCC), and the second terminal TL2 is a ground terminal (GND). In other embodiments, the first terminal TL1 is a ground terminal (GND), and the second terminal TL2 is a power supply terminal (VCC).

In some embodiments, each of the first gate structures MG1, the one of the first contacts MD1 adjacent thereto, and a portion of the dielectric layer 232 between them may form a capacitor C1. first gate structure MG1 and the first contact MD1 next to the first gate structure MG1 (e.g., an adjacent MD1 of the MG1 which separated from the MG1 by the dielectric layer 232) may form electrodes of the capacitor C1. The portion of the dielectric layer 232 between the first gate structure MG1 and the first contact MD1 adjacent to each other may form a dielectric of the capacitor C1. As shown in FIGS. 1 and 2, the first gate structures MG1, the first contacts MD1, and portions of the dielectric layer 232 between the first gate structures MG1 and the first contacts MD1 may form a plurality of capacitors C1 connected in parallel.

The semiconductor device 500 may further include GAA field-effect transistor devices 510 formed on the semiconductor substrate 200 in the active regions 100. In addition, the GAA field-effect transistor devices 510 may be formed over a well region (not shown) in the semiconductor substrate 200. In some embodiments, the GAA field-effect transistor devices 510 include fin structures 210, second gate structures MG2 and epitaxial source/drain features 220SD. The fin structures 210 are formed protruding from the semiconductor substrate 200. In some embodiments, each of the fin structures 210 includes channel layers 210C. In addition, the second gate structure MG2 that is wrapped around the channel layers 210C.

In some embodiments, each of the fin structure 210 extends along direction D1. The fin structures 210 may be formed by patterning a stack (not shown) of alternating channel layers 210C and sacrificial layers (not shown). In addition, the trenches 202 are formed between the fin structures 210 after performing the patterning process. Therefore, the fin structures 210 are separated from each other. Each of the fin structures 210 includes a base portion 210B and an upper portion. The base portion 210B is formed from the semiconductor substrate 200. The upper portion is composed of the patterned stack (not shown) of alternating channel layers 210C and sacrificial layers (not shown) formed on the semiconductor substrate 200. In some embodiments, the fin structures 210 may also serve as active regions 100 to provide the GAA field-effect transistor devices 510 formed thereon. In some embodiments, each of the active regions 100 are located on one corresponding fin structure 210. In some other embodiments, the active regions 100 are different portions of the same fin structure 210. In some embodiments as shown in FIG. 2, three channel layers 210C are formed in the figures. In some other embodiments, the stack of alternating channel layers 210C and sacrificial layers may include more or fewer channel layers 210C. For example, the stack of alternating channel layers 210C and sacrificial layers may include from two to ten channel layers 210C, depending on the desired number of channel layers for forming GAA field-effect transistor devices 510.

In some embodiments, the isolation features 204 are formed on sidewalls of the base portion 210B of each of the fin structures 210 before forming the second gate structures MG2. The isolation features 204 are formed around the base portion 210B of each of the fin structures 210. In addition, top surfaces 204T of the isolation features 204 may be aligned with or located below a top 210BT of the base portion 210B in the channel region of each of the fin structures 210.

The epitaxial source/drain structures 220SD of the GAA field-effect transistor devices 510 are formed in the source/drain recesses (not shown) in the fin structures 210. The epitaxial source/drain structures 220SD are disposed on and connected to opposite sides of the channel layers 210C of the fin structures 210. In some embodiments, the epitaxial source/drain structures 220SD include epitaxial semiconductor materials in-situ or ex-situ doped with an n-type dopant or a p-type dopant. For example, the epitaxial source/drain structures 220SD may include silicon-germanium (SiGe) doped with P-type dopants such as boron. Alternatively, the epitaxial source/drain structures 220SD may include silicon (Si) doped with N-type dopants such as phosphorous (P). In addition, the semiconductor substrate 200 may have the first conductivity type such as P-type, or the second conductivity type such as N-type, depending on requirements.

In some embodiments, source/drain regions of the fin structures 210 are recessed to form source/drain recesses (not shown) by a patterning process. The epitaxial source/drain structures 220SD are then epitaxially grown from the source/drain recesses and the channel layers 210C by an epitaxial growth process includes molecular beam epitaxy (MBE), metal organic chemical vapor deposition (MOCVD), vapor phase epitaxy (VPE), or other applicable epitaxial growth processes.

During the patterning process, the elongated recess portions 204R of the trench isolation feature 204 in the isolation region 110 is simultaneously formed with the source/drain recesses in the fin structures 210 in the active regions 100. In some embodiments, the trench isolation feature 204 and the fin structures 210 has different etching rates during the patterning process, bottoms MD1B of the first contacts MD1 may be aligned with or located above bottoms 220B of the epitaxial source/drain features 220SD.

In some embodiments, each of the second gate structures MG2 of the GAA field-effect transistor devices 510 includes a gate dielectric layer (not shown) wrapping the channel layers 210C and a gate electrode layer (not shown) formed on the gate dielectric layer in the channel region. Therefore, the gate electrode layers (not shown) of the second gate structures MG2 may be separated from the channel layers 210C and the base portion 202B of the fin structures 210 by the gate dielectric layers. In some embodiments, the gate dielectric layer includes high-k dielectric material, other applicable dielectric material or combinations thereof. In some embodiments, the gate dielectric layer is formed by chemical vapor deposition (CVD), physical vapor deposition, (PVD), atomic layer deposition (ALD) or other applicable deposition processes. In some embodiments, the gate electrode layer includes conductive materials, such as metals. In some embodiments, the gate electrode layer is formed by chemical vapor deposition (CVD), physical vapor deposition, (PVD), atomic layer deposition (ALD) or other applicable deposition processes.

In some embodiments, each of the second gate structures MG2 may further include an interfacial layer 224 formed on exposed surfaces of the channel layers 210C to improve adhesion between the channel layers 210C and the gate dielectric layer of the second gate structure MG2. In some embodiments, the interfacial layer 224 includes silicon oxide.

In some embodiments, the first gate structures MG1 is a portion of a GAA field-effect transistor device 510. A top surface TG1 of the first gate structures MG1 may be aligned with a top surface TG2 of the second gate structures MG2. In addition, the first gate structures MG1 and the second gate structures MG2 may be formed simultaneously by the same process(es). Since the top surface 204T of the isolation feature 204 may be aligned with or located below the top 210BT of the base portion 210B of the fin structure 210. In some embodiments, a bottom MG1B of the first gate structure MG1 in the isolation region 110 may be aligned with or located below the top 210BT of the base portion 210B of the fin structure 210.

The GAA field-effect transistor devices 510 may further include gate spacers 226a2 and inner spacers 226b2. The gate spacers 226a2 may be formed on the topmost channel layer 210C of the fin structures 210. In addition, the gate spacers 226a2 may be disposed on opposite sidewalls of each of the second gate structures MG2. The inner spacers 226b2 may be formed between and in contact with the channel layers 210C vertically adjacent to each other. In addition, the inner spacers 226b2 may be in contact with the second gate structures MG2 and the epitaxial source/drain structures 220SD. In some embodiments, the gate spacer 226a2 and inner spacer 226b2 may be a single layer structure or a composite layer structure. In some embodiments, the gate spacers 226a1, 226a2 and inner spacer 226b2 may include the same or similar materials and formed in the same process(es).

The dielectric layer 232 may also cover the top surface and opposite sidewalls of the second gate structures MG2 and filling spaces (not shown) between the second gate structures MG2.

The semiconductor structure 500 may further include at least one second contact MD2 disposed on the epitaxial source/drain features 220SD and passes through the dielectric layer 232. In some embodiments, the top (not shown) of second contact MD2 is aligned with the top surface (not shown) of the dielectric layer 232. In additions, bottoms MD2B of the second contacts MD2 may be located above the bottoms MD1B of the first contacts MD1 in direction D3. The height L1 of the first contact MD1 in the isolation region 110 is greater than the height L2 of the second contacts MD2 in the active region 100. In some embodiments, the difference between the height L1 and the height L2 is equal to or less than the height L220 of the epitaxial source/drain features 220SD.

In some embodiments, the second contacts MD2 are strip shaped. They are arranged along direction D1 and extend along direction D2. The second gate structures MG2 and the second contacts MD2 may be parallel to each other in directions D2 and D3.

In some embodiments, the second contacts MD2 are arranged periodically along direction D1. The second contacts MD2 may be arranged alternatingly with the second gate structures MG2. For example, each of the second gate structures MG2 is located between two the second contacts MD2. Each of the second contacts MD2 is located between two of the second gate structures MG2. For example, the adjacent two second contacts MD2 may be disposed on opposite sides of the corresponding second gate structures MG2.

In some embodiments, the first contact MD1 in the isolation region 110 and the second contact MD2 in the active region 100 may include the same or similar materials and formed in the same process(es). Therefore, the first contact MD1 and the second contact MD2 may also called source/drain contacts MD1 and MD2.

The semiconductor structure 500 may further include vias 240G2, 240SD2 formed on the dielectric layer 232, the second gate structures MG2 and the second contacts MD2. The vias 240G2 are formed passing through the intermetal dielectric (IMD) layer 242 and portions of the dielectric layer 232 directly above the second gate structures MG2. In addition, the vias 240G2 are electrically coupled to the second gate structures MG21. The vias 240SD2 are located directly above the second contacts MD2. The vias 240SD2 are formed passing through the intermetal dielectric (IMD) layer 242. In addition, the vias 240SD2 are electrically coupled to the second contacts MD2.

In some embodiments in which the GAA field-effect transistor device 510 is operated as a field-effect transistor, the second gate structure MG2 and the epitaxial source/drain features 220SD disposed on opposite sides of the corresponding second gate structure MG2 are electrically coupled to different terminals by the vias 240G2, 240SD2.

In some embodiments in which the GAA field-effect transistor devices 510 is operated as a capacitor, the second gate structure MG2 is electrically coupled to the first terminal (e.g., the first terminal TL1), and the epitaxial source/drain features 220SD disposed on opposite sides of the corresponding second gate structure MG2 are electrically coupled to the second terminal (e.g., the second terminal TL2).

Compared with the capacitor formed by the GAA field-effect transistor devices 510, the capacitor C1 formed in the isolation region 110 may have a greater capacitance due to the greater area of the electrode (the height L1 of the first contact MD1 is greater than the height L2 of the second contact MD2). In addition, the electrodes (e.g., the first gate structure MG1 and the first contact MD1) of the capacitor C1 are formed on and in contact with the trench isolation feature 204 having a thick thickness. The capacitor C1 may avoid the leakage problem.

The semiconductor structure 500 may further include gate isolation features CMD disposed on the semiconductor substrate 200. The gate isolation features CMD are disposed in the isolation region 110 (outside the active regions 100) and extend along direction D1. In some embodiments, the gate isolation features CMD are used to divide the strip-shaped first gate structures MG1 in the isolation region 110 and the strip-shaped second gate structures MG2 in the active regions 100 into sub-gate structures. The gate isolation features CMD may be also used to divide the strip-shaped first contacts MD2 in the isolation region 110 and the strip-shaped second contacts MD2 in the active regions 100 into sub-contacts. In some embodiments, the gate isolation features CMD include dielectric materials.

Embodiments provide a semiconductor structure. The semiconductor structure includes a trench isolation feature (e.g., the trench isolation feature 204), a gate structure (e.g., the first gate structure MG1) and a source/drain contact (e.g., the first contact MD1). The gate structure and the source/drain contact are disposed directly on the trench isolation feature. The gate structure and the source/drain contact next to the gate structure form electrodes of a capacitor (e.g., the capacitor C1). Compared with the capacitor formed in the GAA field-effect transistor device (e.g., the GAA field-effect transistor devices 510), the capacitor formed directly on the trench isolation feature may have a greater capacitance due to the greater area (larger height L1) of the source/drain contact (the electrode). In addition, the electrodes (e.g., the gate structure and the source/drain contact) of the capacitor are formed on and in contact with the trench isolation feature having a thicker thickness. The capacitor may avoid the leakage problem.

In some embodiments, the semiconductor structure further includes gate spacers disposed on opposite sidewalls of the gate structure.

In some embodiments, the semiconductor structure further includes additional gate structures and additional source/drain contacts disposed directly on the trench isolation feature. Each of the gate structures is located between two of the source/drain contacts, and each of the source/drain contacts is located between two of the gate structures.

In some embodiments, the gate structure and the source/drain contact are surrounded by a dielectric layer which is disposed directly on the trench isolation feature.

In some embodiments, the gate structure is connected to a via.

In some embodiments, the source/drain contact is connected to a via.

In some embodiments, the trench isolation feature is disposed on a semiconductor substrate.

In some embodiments, the gate structure is a portion of a gate-all-around (GAA) field-effect transistor device.

In some embodiments, a gate electrode of the gate structure and the source/drain contact include metal.

In some embodiments, the gate structure and the source/drain contact are strip shaped and parallel to each other.

Embodiments provide semiconductor structure. The semiconductor structure includes a semiconductor substrate, a trench isolation feature and first contacts. The semiconductor substrate has an active region and an isolation region surrounding the active region. The trench isolation feature is disposed in the isolation region. The first gate structure is disposed on and in contact with the trench isolation feature. The first contacts are disposed on opposite sides of the first gate structure and in contact with trench isolation feature. The first gate structure is electrically coupled to a first power terminal, and the first contacts are electrically coupled to a second power terminal.

In some embodiments, the semiconductor structure further includes a dielectric layer covering the first gate structure and the first contacts. The first gate structure, the first contacts and portions of the dielectric layer between the first gate structure and the first contacts form capacitors connected in parallel.

In some embodiments, the first power terminal is a power supply terminal, and the second power terminal is a ground terminal.

In some embodiments, the first gate structure and the first contacts are strip shaped. They are arranged along a first direction and extend along a second direction.

In some embodiments, the trench isolation feature includes elongated recess portions arranged periodically along a first direction and extending along a second direction that is different from the first direction. The first gate structure is disposed on a top surface portion of the trench isolation feature between the elongated recess portions. The gate structure extends along the second direction.

In some embodiments, the first contacts are respectively disposed in the elongated recess portions, wherein each of the elongated recess portions is in contact with one of the first contacts.

In some embodiments, the semiconductor structure further includes a gate-all-around (GAA) field-effect transistor device. The gate-all-around (GAA) field-effect transistor device is formed in the active region extending along a first direction. The GAA field-effect transistor device includes a second gate structure and epitaxial source/drain features. The second gate structure extends along a second direction. The epitaxial source/drain features are disposed on opposite sides of the second gate structure in the first direction. First bottoms of the first contacts are aligned with or located above second bottoms of the epitaxial source/drain features.

In some embodiments, the semiconductor structure further includes second contacts respectively disposed on the epitaxial source/drain features Third bottoms of the second contacts are located above the first bottoms of the first contacts.

In some embodiments, the GAA field-effect transistor device includes a fin structure. The fin structure is formed protruding from the semiconductor substrate. The fin structure forms the active region. The fin structure includes a base portion and an upper portion. The upper portion an upper portion channel layers extending along the first direction and wrapped by the second gate structure. A fourth bottom of the first gate structure is aligned with or located below a first top of the base portion.

In some embodiments, the second gate structure is electrically coupled to the first power terminal, and the epitaxial source/drain features are electrically coupled to the second power terminal.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a trench isolation feature; and
a gate structure and a source/drain contact next to the gate structure, disposed directly on the trench isolation feature,
wherein the gate structure and the source/drain contact form electrodes of a capacitor.

2. The semiconductor structure as claimed in claim 1, further comprising:
gate spacers disposed on opposite sidewalls of the gate structure.

3. The semiconductor structure as claimed in claim 1, further comprising:
additional gate structures and additional source/drain contacts, disposed directly on the trench isolation feature,
wherein each of the gate structures is located between two of the source/drain contacts, and
each of the source/drain contacts is located between two of the gate structures.

4. The semiconductor structure as claimed in claim 1, wherein the gate structure and the source/drain contact are surrounded by a dielectric layer which is disposed directly on the trench isolation feature.

5. The semiconductor structure as claimed in claim 1, wherein the gate structure is connected to a via.

6. The semiconductor structure as claimed in claim 1, wherein the source/drain contact is connected to a via.

7. The semiconductor structure as claimed in claim 1, wherein the trench isolation feature is disposed on a semiconductor substrate.

8. The semiconductor structure as claimed in claim 1, wherein the gate structure is a portion of a gate-all-around (GAA) field-effect transistor device.

9. The semiconductor structure as claimed in claim 1, wherein a gate electrode of the gate structure and the source/drain contact comprise metal.

10. The semiconductor structure as claimed in claim 1, wherein the gate structure and the source/drain contact are strip shaped and parallel to each other.

11. A semiconductor structure, comprising:
a semiconductor substrate having an active region and an isolation region surrounding the active region;
a trench isolation feature disposed in the isolation region;
a first gate structure disposed on and in contact with the trench isolation feature; and
first contacts disposed on opposite sides of the first gate structure and in contact with trench isolation feature,
wherein the first gate structure is electrically coupled to a first power terminal, and the first contacts are electrically coupled to a second power terminal.

12. The semiconductor structure as claimed in claim 11, further comprising:
a dielectric layer covering the first gate structure and the first contacts, wherein the first gate structure, the first contacts and portions of the dielectric layer between the first gate structure and the first contacts form capacitors connected in parallel.

13. The semiconductor structure as claimed in claim 11, wherein the first power terminal is a power supply terminal, and the second power terminal is a ground terminal; or
the first power terminal is a ground terminal, and the second power terminal is a power supply terminal.

14. The semiconductor structure as claimed in claim 11, wherein the first gate structure and the first contacts are strip shaped, arranged along a first direction (D1), and extend along a second direction.

15. The semiconductor structure as claimed in claim 11, wherein:
the trench isolation feature comprises elongated recess portions arranged periodically along a first direction and extending along a second direction that is different from the first direction, and
the first gate structure is disposed on a top surface portion of the trench isolation feature between the elongated recess portions, wherein the gate structure extends along the second direction.

16. The semiconductor structure as claimed in claim 15, wherein the first contacts are respectively disposed in the elongated recess portions, wherein each of the elongated recess portions is in contact with one of the first contacts.

17. The semiconductor structure as claimed in claim 11, further comprising:
a gate-all-around (GAA) field-effect transistor device formed in the active region extending along a first direction, wherein the GAA field-effect transistor device comprises:
a second gate structure extending along a second direction; and
epitaxial source/drain features disposed on opposite sides of the second gate structure in the first direction, wherein first bottoms of the first contacts are aligned with or located above second bottoms of the epitaxial source/drain features.

18. The semiconductor structure as claimed in claim 17, further comprising:
second contacts respectively disposed on the epitaxial source/drain features, wherein third bottoms of the second contacts are located above the first bottoms of the first contacts.

19. The semiconductor structure as claimed in claim 17, wherein the GAA field-effect transistor device further comprises:
a fin structure formed protruding from the semiconductor substrate, wherein the fin structure forms the active region, and wherein the fin structure comprises:
a base portion; and
an upper portion comprises channel layers extending along the first direction and wrapped by the second gate structure,
wherein a fourth bottom of the first gate structure is aligned with or located below a first top of the base portion.

20. The semiconductor structure as claimed in claim 17, wherein the second gate structure is electrically coupled to the first power terminal, and the epitaxial source/drain features are electrically coupled to the second power terminal.
